(19) United States
(12) Patent Application Publication
(10) Pub. No.: US 2014/0225152 A1
(43) Pub. Date: Aug. 14, 2014

(54) WIRING BOARD AND LIGHT EMITTING DEVICE USING SAME, AND MANUFACTURING METHOD FOR BOTH

(71) Applicant: Panasonic Corporation, Osaka (JP)

(72) Inventors: Toshiyuki ASAHI, Osaka (JP); Naoyuki TANI, Osaka (JP); Yoshito KITAGAWA, Osaka (JP); Yuta OKAZAKI, Osaka (JP)

(73) Assignee: Panasonic Corporation, Osaka (JP)

(21) Appl. No.: 14/257,099

(22) Filed: Apr. 21, 2014

Related U.S. Application Data
(63) Continuation of application No. PCT/JP2012/007009, filed on Nov. 1, 2012.

(30) Foreign Application Priority Data
Nov. 7, 2011 (JP) 2011-243302

(51) Int. Cl. H01L 33/62; H05K 1/02

(52) U.S. Cl. CPC H01L 33/62; H05K 1/0296; H05K 2201/09209
USPC 257/99; 438/26; 174/262; 174/257; 174/258

(57) ABSTRACT

A wiring board includes a base in which plate wirings formed of a metal plate are integrally formed with an insulating portion made of resin or a resin composition and surface wirings electrically connected to the plate wirings. The base has first and second surfaces on which the surface wirings are formed. The surface wirings are thinner than the plate wirings, and the minimum wiring gap between the surface wirings is smaller than the minimum wiring gap between the plate wirings. One of the plate wirings has substantially the same shape as that of a region where the first top-surface wiring on the first surface and the first bottom-surface wiring on the second surface overlap with each other in the normal direction of the first surface. The first top-surface wiring and the first bottom-surface wiring are connected to each other through the above-mentioned one of the plate wirings.

### BACKGROUND

1. Technical Field

The present technical field relates to a wiring board including plate wirings, an insulating portion integrally formed therewith, and surface wirings formed on the principal planes thereof. The technical field also relates to a light emitting device including the wiring board and a light emitting element mounted thereon, and to methods for manufacturing the wiring board and the light emitting device.

2. Background Art

Light emitting elements such as light emitting diodes (hereinafter, LEDs) and semiconductor lasers are used in various light emitting devices. Among them, light emitting devices including LED bare chips are more compact and efficient than already available light sources with discharge or emission, and also have advantageous properties such as being resistant to vibration and repeated on-off operations. For these advantages, the use of light emitting devices has been expanding mainly in the illumination field.

A light emitting device including an LED is composed, for example, of an LED bare chip and a wiring board on which the LED bare chip is mounted. Some of such light emitting devices further include a phosphor-containing cover layer covering the LED bare chip. For example, when a blue LED such as a GaN-based compound semiconductor is covered with a cover layer containing a yellow fluorescent substance, the light emitting device emits white light.

An LED bare chip can be mounted on a wiring board by, for example, wire bonding or flip-chip mounting with bumps made of Au or other material. Flip-chip mounting is advantageous because it does not cause projection of wire shadow and has a low conductor resistance due to the short connection distance.

Increasing the output of a light emitting element as a semiconductor element requires increasing the input current. Along with the recent increasing demand for high power output, it is now often the case that a plurality of high-power LEDs and optical elements are used in combination. As optical elements increase in output and the number of use, their heating values increase.

Flip-chip mounting has another advantage; a light emitting layer as the heat source is close to the wiring board, thereby having a low thermal resistance. Properties of a light emitting element deteriorate with heat; it is therefore important to ensure heat radiation. The heat of the light emitting element is transferred through the wiring board mainly to the mother board mounted with the wiring board and then is dispersed in the mother board. It is therefore often the case that a mother board is provided with a heat sink.

Since a wiring board mounted with a light emitting element is required to have low thermal and electrical resistances, a ceramic substrate or a metal substrate is used in the wiring board. A ceramic substrate is superior in thermal resistance because its ceramic portion which is to be the insulating portion has a higher thermal conductivity than a resin insulating layer formed on a metal substrate. Furthermore, fine wiring patterns allowing a semiconductor to be flip-chip mounted as a bare chip can be formed on a ceramic substrate. A ceramic substrate is superior also in heat resistance to the metal substrate with the resin insulating layer. For these superiorities, ceramic substrates are suitable for use in products requiring high power, such as power supplies and air conditioners.

In a general ceramic wiring board, the first surface wiring on which a light emitting element is mounted and the second surface wiring mounted on a mother board are electrically connected to each other through vias. The light emitting element mounted on a wiring board is supplied with electric power from the wiring of the mother board, passing along the second surface wiring, the vias, and the first surface wiring in that order. Therefore, the loss can be reduced and the efficiency is improved by reducing the electrical resistance along the second surface wiring, the vias, and the first surface wiring. The heat generated in the light emitting element is transferred to the mother board through the wiring board. Free electrons have high heat propagation. Therefore, the thermal resistance along the second surface wiring, the vias, and the first surface wiring is important in terms of heat transfer, and has a large number of vias to reduce the electrical and thermal resistances. To reduce the electrical and thermal resistances, it is also effective to use flip-chip mounting without wire bonding.

A wiring board with a metal substrate, on the other hand, has a higher thermal resistance than the wiring board with the ceramic substrate because the resin insulating layer formed on the metal substrate has a lower thermal conductivity than ceramics.

In general, the size of the gap between wiring patterns formed on the same surface largely depends on the thickness of the material of the wirings. The term “thickness” here indicates the length in the direction orthogonal to the surface on which the wirings are formed. The minimum wiring gap between the wiring patterns has a width approximately equal to the thickness of the material of the wirings as a result of the wiring process. The term “minimum wiring gap” here indicates the smallest gap between adjacent wirings.

When forming wiring patterns on a metal substrate formed of a metal plate, the metal plate is etched or punched. It is difficult, however, to form fine wiring patterns because the minimum wiring gap between the wiring patterns is as small as the thickness of the metal plate due to process features. It is therefore difficult to surface-mount, on a wiring board including a metal plate, a light emitting element in which the gap between wiring patterns is smaller than the thickness of the metal plate. For this reason, the light emitting element and the wiring board are electrically connected to each other through wire bonding.

A general approach to reducing the thermal resistance is to use an insulating layer with a high thermal conductivity, such as aluminum nitride shown in Japanese Patent No. 4675906. Another proposed approach is to use a wiring board including a metal cabinet shown in Japanese Unexamined Patent Publication No. 2006-066631. In the wiring board of Japanese Unexamined Patent Publication No. 2006-066631, the first surface wiring and the second surface wiring are connected to each other through vias.

### SUMMARY

The present disclosure is directed to provide a wiring board which has a low electrical resistance so as to reduce an electrical loss, and also has a low thermal resistance so that a light emitting element mounted thereon can have high reliability, longevity, and other properties. The disclosure is also directed to provide a light emitting device including the wiring board and the light emitting element mounted thereon, and methods for manufacturing the wiring board and the light emitting device.

The wiring board according to various embodiments includes a base, a plurality of top-surface wirings, and a plurality of bottom-surface wirings. The base includes an insulating portion, a plurality of plate wirings including first and second plate wirings formed of metal plates. The base has a first surface and a second surface opposite to the first surface. The insulating portion is made of resin, a resin composition or a glass composition and is integrally formed with the plurality of plate wirings so as to be substantially as thick as the plurality of plate wirings. The plurality of top-surface wirings are metal-plated on the first surface so as to be thinner than the plurality of plate wirings. The plurality of top-surface wirings include first and second top-surface wirings electrically connected to the first and second plate wirings, respectively. The plurality of bottom-surface wirings are metal-plated on the second surface so as to be thinner than the plurality of plate wirings. The plurality of bottom-surface wirings include first and second bottom-surface wirings electrically connected to the first and second plate wirings, respectively. The minimum wiring gap between the plurality of top-surface wirings is smaller than the minimum wiring gap between the plurality of plate wirings. The first plate wiring has substantially the same shape as that of a region in which the first top-surface wiring and the first bottom-surface wiring overlap with each other in the normal direction of the first surface, and are connected to each other through the first plate wiring.

In the above configuration, the use of the plate wirings formed of the metal plates allows connecting the first top-surface wiring and the first bottom-surface wiring through a material having low electrical and thermal resistances. Furthermore, the plate wirings and the insulating portion are made to be substantially as thick as each other; therefore, the surface wirings electrically connected directly to the plate wirings can be formed with high accuracy. In addition, the surface wirings are thinner than the plate wirings, and the minimum wiring gap between the surface wirings is smaller than the minimum wiring gap between the plate wirings; therefore, the wiring patterns are compatible with bare chip mounting. The first plate wiring has substantially the same shape as that of a region where the first top-surface wiring and the first bottom-surface wiring overlap with each other in the normal direction of the first surface; this leads to an increase in the area of the plate wirings and a decrease in the thermal resistance. This results in a decrease in the electrical and thermal resistances between the light emitting element mounted on the surface wiring and the mother board. Furthermore, the above configuration either decreases the temperature of the light emitting element mounted on the wiring board, or increases the electric power applied at the same temperature of the light emitting element. As a result, the light emitting device is more reliable.

### BRIEF DESCRIPTION OF DRAWINGS

FIG. 1 is a perspective view of a wiring board according to an exemplary embodiment.

FIG. 2 is a sectional view taken along line 2-2 of the wiring board shown in FIG. 1.

FIG. 3 is a sectional view taken along line 3-3 of the wiring board shown in FIG. 1.

FIG. 4A is a plan view of a first surface of the wiring board shown in FIG. 1.

FIG. 4B is a perspective plan view of a second surface of the wiring board shown in FIG. 1.

FIG. 4C is a plan view of regions in which top-surface wirings shown in FIG. 4A and bottom-surface wirings shown in FIG. 4B overlap with each other and are connected to each other through a plate wiring.

FIG. 4D is a plan view of a region in which the top-surface wirings shown in FIG. 4A and the bottom-surface wirings shown in FIG. 4B overlap with each other and are not connected to each other through a plate wiring.

FIG. 5A is a plan view of a first surface of another wiring board according to the exemplary embodiment.

FIG. 5B is a perspective plan view of a second surface of the wiring board shown in FIG. 5A.

FIG. 5C is a plan view of regions in which top-surface wirings shown in FIG. 5A and bottom-surface wirings shown in FIG. 5B overlap with each other and are connected to each other through a plate wiring.

FIG. 6 is a perspective view of a light emitting device according to the exemplary embodiment.

FIG. 7 is a sectional view taken along line 7-7 of the light emitting device shown in FIG. 6.

FIG. 8 is a sectional view of another light emitting device according to the exemplary embodiment.

FIG. 9A is a sectional view showing a step of a method of manufacturing the light emitting device shown in FIG. 8.

FIG. 9B is a sectional view showing a step subsequent to the step of FIG. 9A in the method of manufacturing the light emitting device.

FIG. 9C is a sectional view showing a step subsequent to the step of FIG. 9B in the method of manufacturing the light emitting device.

FIG. 9D is a sectional view showing a step subsequent to the step of FIG. 9C in the method of manufacturing the light emitting device.

FIG. 9E is a sectional view showing a step subsequent to the step of FIG. 9D in the method of manufacturing the light emitting device.

FIG. 9F is a sectional view showing a step subsequent to the step of FIG. 9E in the method of manufacturing the light emitting device.

FIG. 10 is a perspective view of wiring boards arranged in an array according to the exemplary embodiment.

FIG. 11 is a perspective view of the wiring boards arranged in the array as shown in FIG. 10 and then mounted with respective light emitting elements thereon.

FIG. 12 is a perspective view of the light emitting elements shown in FIG. 11 which are covered with a cover layer.

FIG. 13 is a perspective view of a conventional ceramic wiring board.

FIG. 14 is a perspective view taken along line 14-14 of the ceramic wiring board shown in FIG. 13.

FIG. 15 is a sectional view taken along line 15-15 of the ceramic wiring board shown in FIG. 13.

FIG. 16A is a plan view of a wiring pattern where plate wirings occupies 10 vol % in an example of example of the embodiment.

FIG. 16B is a plan view of a wiring pattern where plate wirings occupies 20 vol % in the example of the embodiment.

FIG. 16C is a plan view of a wiring pattern where plate wirings occupies 40 vol % in the example of the embodiment.

FIG. 16D is a plan view of a wiring pattern where plate wirings occupies 60 vol % in the example of the embodiment.

FIG. 16E is a plan view of a wiring pattern where plate wirings occupies 80 vol % in the example of the embodiment.

FIG. 17 is a plan view of the wiring pattern of a surface wiring in the example of the embodiment.

FIG. 18 is a plan view of a wiring pattern of conductive vias formed in a ceramic or resin wiring board to compare with the example of the embodiment.

FIG. 19 is a graph showing the heating value dependence of the temperature difference between the surfaces of each wiring board according to the example of the embodiment.

FIG. 20 is a graph showing the temperature dependence of the elastic modulus of the wiring board and the resin wiring board according to the example of the embodiment.

FIG. 21 is a graph showing the load dependence of the bonding strength of gold balls in the example of the embodiment.

### DETAIL DESCRIPTION OF PREFERRED EMBODIMENTS

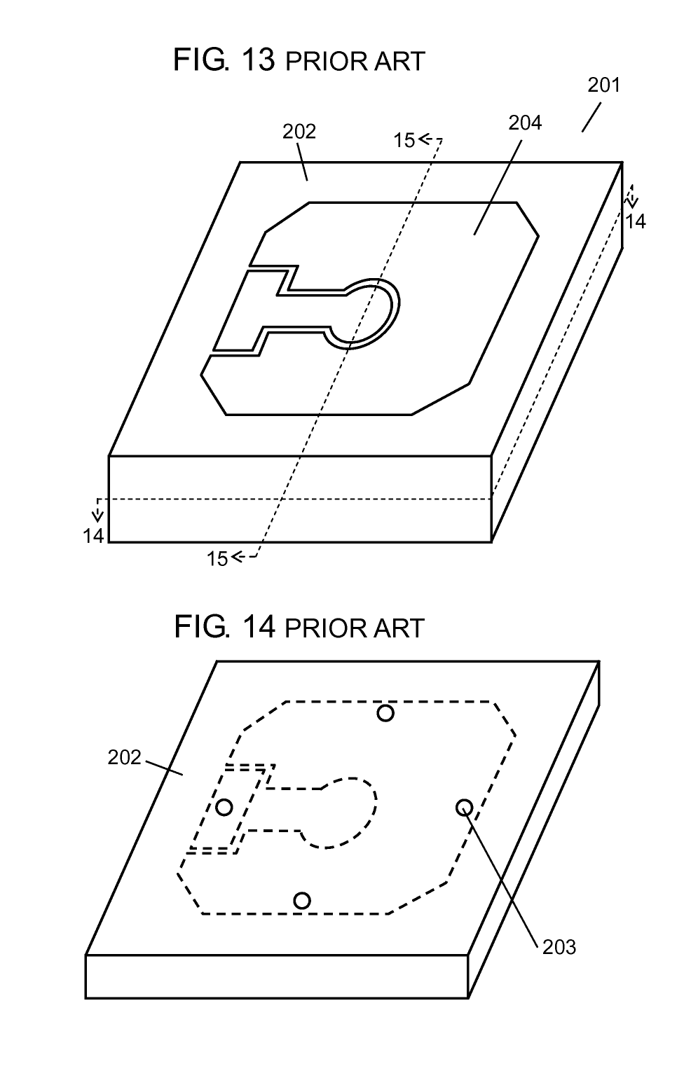

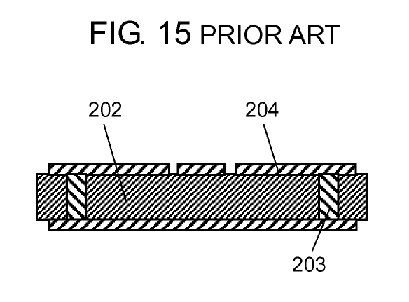

Prior to describing an exemplary embodiments, problems in the conventional configuration will now be described with reference to FIGS. 13 through 15. FIG. 13 is a perspective view of ceramic wiring board 201 including ceramic insulating layer 202. FIG. 14 is a perspective view taken along line 14-14 of ceramic wiring board 201 shown in FIG. 13. FIG. 15 is a sectional view taken along line 15-15 of ceramic wiring board 201 shown in FIG. 13.

As shown in FIG. 15, ceramic wiring board 201 has a pair of surfaces, surface wirings 204 provided on the surfaces are electrically connected to each other through conductive vias 203. In this configuration, the area for making an electrical connection between surface wirings 204 on both surfaces is no larger than the total cross-sectional area of vias 203, which limits the thermal and electrical resistances. Meanwhile, vias 203 are formed by, for example, printing and filling in ceramic wiring board 201; then sintered to increase their density; and finally electrically connected to surface wirings 204. Therefore, vias 203 need to be made of a material to be sintered and resistant to printing and filling. This limits the materials that can be used as vias 203, thereby limiting the reduction in thermal and electrical resistances.

In the wiring board including the metal plate, on the other hand, the resin insulating layer formed on the metal plate has a much lower thermal conductivity than ceramics as described above. For this reason, the wiring board including the metal plate has a higher thermal resistance than the wiring board with the ceramic substrate. Regarding heat resistance, the wiring board including the metal plate deteriorates in structural and wiring strengths at high temperatures of 200° C. to 350° C. exceeding the glass transition temperature of the resin.

Also, as described above, it is difficult to surface-mount a semiconductor, on the wiring board including the metal plate, where the semiconductor has the gap between wiring patterns smaller than the thickness of the metal plate. However, electrically connecting the wiring board and the semiconductor by, for example, wire bonding would cause an increase in electrical resistance.

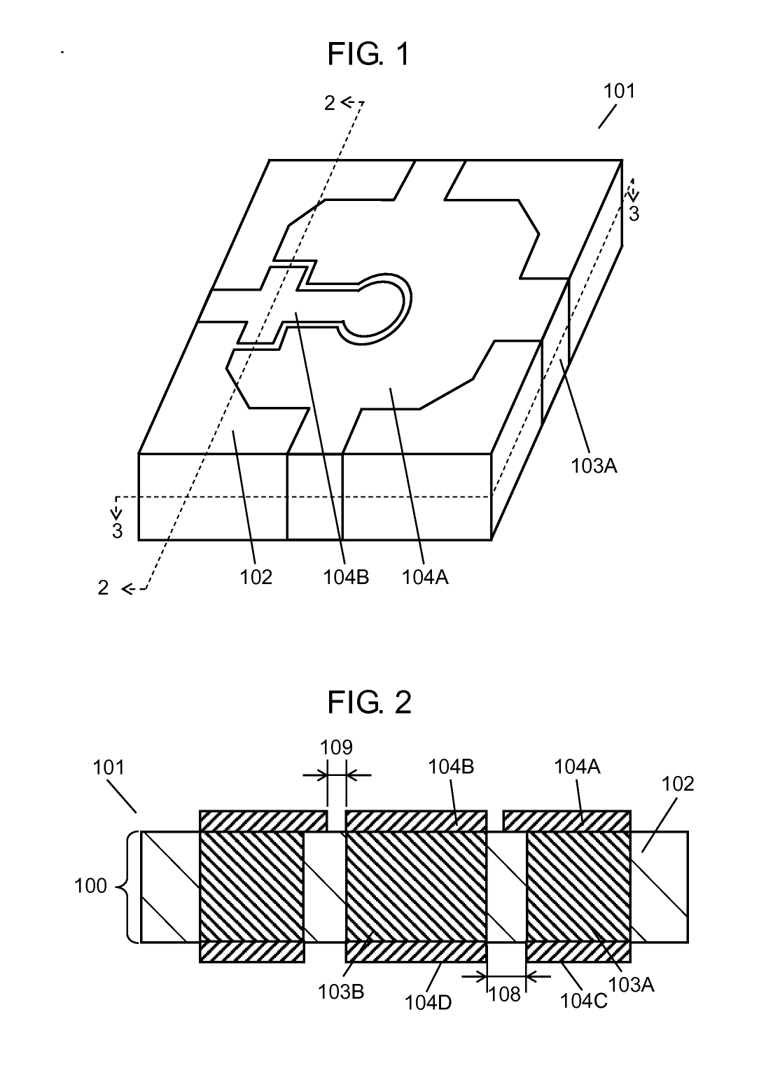

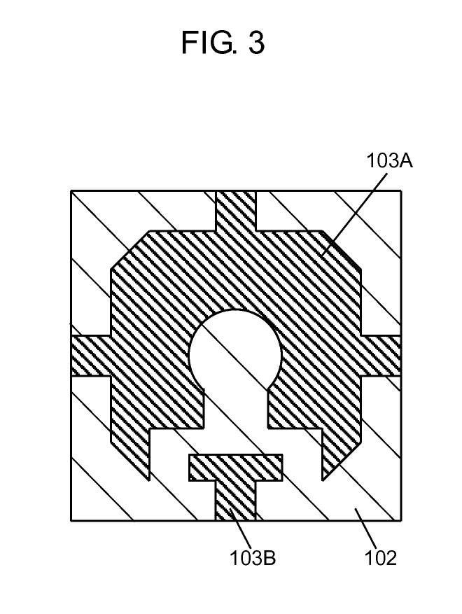

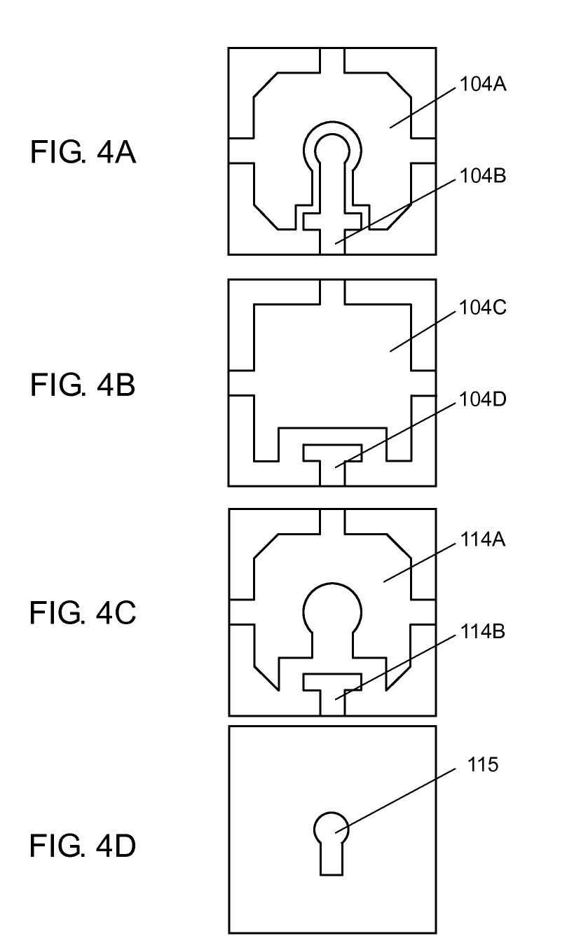

The exemplary embodiments, which have been developed to solve these problems, will now be described as follows. FIG. 1 is a perspective view of wiring board 101 according to the exemplary embodiment. FIG. 2 is a sectional view taken along line 2-2 of wiring board 101. FIG. 3 is a sectional view taken along line 3-3 of wiring board 101. FIG. 4A is a plan view of a first surface of wiring board 101. FIG. 4B is a perspective plan view of a second surface of wiring board 101. FIG. 4C is a plan view of regions in which top-surface wirings shown in FIG. 4A and bottom-surface wirings shown in FIG. 4B overlap with each other and are connected to each other through a plate wiring. FIG. 4D is a plan view of a region in which the top-surface wirings shown in FIG. 4A and the bottom-surface wirings shown in FIG. 4B overlap with each other and are not connected to each other through a plate wiring.

Wiring board 101 includes base 100, first top-surface wiring 104A, second top-surface wiring 104B, first bottom-surface wiring 104C, and second bottom-surface wiring 104D. Base 100 includes first plate wiring 103A, second plate wiring 103B (hereinafter, plate wirings 103A and 103B), and insulating portion 102.

Plate wirings 103A and 103B are formed of metal plates, and are formed uniformly in shape from the first to the second surface corresponding to the upper and lower surfaces, respectively, of base 100.

Insulating portion 102 is made of resin or a resin composition, and is integrally formed with plate wirings 103A and 103B. The insulating portion is made substantially as thick as plate wirings 103A and 103B.

First top-surface wiring 104A and second top-surface wiring 104B (hereinafter, surface wirings 104A and 104B) are formed on the first surface, which is the upper surface of base 100. On the other hand, first bottom-surface wiring 104C and second bottom-surface wiring 104D (hereinafter, surface wirings 104C and 104D) are formed on the second surface, which is the lower surface of base 100. The second surface is opposite and parallel to the first surface. Surface wirings 104A to 104D are formed thinner than plate wirings 103A and 103B by metal plating. Surface wirings 104A and 104C are electrically connected to plate wiring 103A, whereas surface wirings 104B and 104D are electrically connected to plate wiring 103B. Surface wirings 104A and 104B have minimum wiring gap 109 therebetween, which is smaller than minimum wiring gap 108 between plate wirings 103A and 103B.

Although the configuration shown in FIGS. 1 through 4B includes two plate wirings, two top-surface wirings, and two bottom-surface wirings, the number of each of these components may be three or more. Each component will now be described in detail. Insulating portion 102 is either resin or a resin composition (resin and/or insulating filler-containing resin) or a glass composition. The type of resin is not particularly limited and can be, for example, any of the followings: thermosetting resin, thermoplastic resin, and photocuring resin. Specific examples include epoxy resin, silicone resin, polyimide resin, phenol resin, isocyanate resin, triazine resin, melamine resin, polyphenylene sulfide, polyarylate, polysulfone, polyethersulfone, polyetherimide, polyamide-imide, polyether ether ketone, liquid crystalline polyester, and their modified resins.

Alternatively, these resins may be used in combination of two or more, and in addition, various kinds of hardening agents or hardening accelerators may be used depending on application.

Among the above-mentioned resins, those suitable for use at high temperatures because of their high heat resistance are as follows: epoxy resin, silicone resin, polyimide resin, phenol resin, isocyanate resin, polyphenylene sulfide, polyarylate, polysulfone, polyethersulfone, polyetherimide, polyamide-imide, polyether ether ketone, and liquid crystalline polyester.

Epoxy resin is suitable for use in wiring boards because of its properties such as strength and adhesion. Examples of preferable base compounds of epoxy resin include glycidyl ether epoxy resin, alicyclic epoxy resin, glycidyl amine epoxy resin, glycidyl ester epoxy resin, and their modified epoxy resin.

Polytetrafluoroethylene (PTFE) and other fluorine resins, polyphenylene oxide (PPO), polyphenylene ether (PPE), liquid crystal polymer, and their modified resins have a low dielectric loss tangent. Therefore, the high-frequency characteristics of insulating portion 102 can be improved when above-mentioned resins are used.

As a hardening agent to be used with resin (for example, epoxy resin), an amine- or phenol-based hardening agent is usable. Other usable examples of the hardening agent include dicyandiamide, diaminodiphenyl methane, diaminodiphenylsulfone, phthalic anhydride, pyromellitic dianhydride, and polyfunctional phenols such as phenol novolac and cresol novolac. These hardening agents may be used alone or in combination of two or more thereof. Their types and quantities are not limited and can be properly determined depending on the following: the reactivity with epoxy resin; process conditions of the resin such as the viscosity and the curing temperature; and properties of the cured resin such as the heat resistance, the strength, and the transparency.

The type of hardening accelerator to be used with resin is not particularly limited, and can be, for example, an imidazole compound, an organic phosphorus compound, an amine salt, an ammonium salt, or a combination of two or more thereof. It is also possible to add rubber or thermoplastic resin to the resin composition in order to improve moldability.

The proper selection of the types of insulating filler and resin can control physical properties of insulating portion 102 such as linear expansion coefficient, thermal conductivity, dielectric constant, weather resistance, and flame retardance. Specific examples of the insulating filler includes Al₂O₃, MgO, SiO₂, BN, AlN, Si₃N₄, PTFE, MgCO₃, Al(OH)₃, Mg(OH)₂, AlO(OH), and TiO₂. Using Al₂O₃, BN, AlN, or MgO can improve the thermal conductance of insulating portion 102. In addition, Al₂O₃ and MgO have the advantage of being inexpensive. Using SiO₂, Si₃N₄, BN, or PTFE allows insulating portion 102 to have a low dielectric constant. Especially, SiO₂ is suitable for use in mobile phones and other similar devices because of its low specific gravity. Using SiO₂ or BN as the insulating filler decreases the linear expansion coefficient, and using TiO₂ improves the whitening and weather resistance of insulating portion 102. Using Al(OH)₃, Mg(OH)₂, or AlO(OH) provides insulating portion 102 with flame retardance.

The insulating filler has an average particle size in the range from 0.05 μm to 20 μm, inclusive, and preferably in the range from 0.1 μm to 10 μm, inclusive. If the average particle size of the insulating filler is too small, insulating portion 102 would be more viscous, thereby decreasing its workability and compactability when plate wirings 103A and 103B are embedded therein. If, on the other hand, the average particle size of the insulating filler is too large, the withstand voltage of surface wirings 104A to 104D would decrease.

The shape of the particles of the insulating filler is not particularly limited. Specifically, the particles can be spherical, flat, polygonal, scale-like, flake-like, or with projections on their surfaces. Furthermore, they may be primary or secondary particles.

In addition, these insulating fillers may be surface-treated to improve their moisture resistance, adhesive strength, and dispersibility. Specific examples of the surface treatment include the use of a silane coupling agent, a titanate coupling agent, a phosphate ester, a sulfonate ester, and a carboxylate ester; alumina coating; and silica coating. Furthermore, the insulating fillers may be coated with a silicon-based material. In order to increase the filling rate, it is possible to use a mixture of different inorganic fillers having different particle size distributions.

Insulating portion 102 may contain an additive. Examples of the additive include a wetting dispersant; a coloring agent; a coupling agent; a light stabilizer such as an ultraviolet absorber; an antioxidant; and a mold release agent. Using a wetting dispersant equalizes the distribution of the insulating filler in the resin. Using a coloring agent to color insulating portion 102 allows wiring board 101 to be easily recognized by an automatic recognition device. Using a coupling agent increases the adhesive strength between the resin and the insulating filler, thereby improving the insulating properties of insulating portion 102. Using a light stabilizer reduces the deterioration of insulating portion 102 due to ultraviolet light or other factors. Using an antioxidant reduces the deterioration of insulating portion 102 due to heat. Using a mold release agent improves the mold-release characteristics of insulating portion 102, thereby increasing productivity.

In a case that insulating portion 102 is made of a glass composition, insulating portion 102 has higher heat resistance than being made of a resin composition, and is prevented from being discolored especially at high temperatures. Insulating portion 102 made of a glass composition can contain an insulating filler as in the case of being made of a resin composition.

Insulating portion 102 is integrally formed with plate wirings 103A and 103B, for example, as follows. An uncured resin composition is filled between plate wirings 103A and 103B, and then is cured so as to be integral with plate wirings 103A and 103B. Insulating portion 102 formed in this manner has a lower thermal resistance than the above-described conventional configuration including a low thermal-conductive insulating layer.

Insulating portion 102 is substantially as thick as plate wirings 103A and 103B. The thickness here indicates the length in the direction orthogonal to the first and second surfaces of base 100. Making them as thick as each other allows surface wirings 104A to 104D to be formed with high precision. The term “substantially as thick as” indicates that the difference in thickness between insulating portion 102 and plate wirings 103A and 103B is within about ±5%.

Among the first and second surfaces of base 100 in which plate wirings 103A and 103B are integrally formed with insulating portion 102, the second surface is the surface (component side) to be mounted on a mother board, and may be of depressed shape to improve mountability on the mother board.

The surfaces of insulating portion 102 may be subjected to desmearing or other roughening treatment. The roughening treatment improves the adhesion between surface wirings 104A to 104D and insulating portion 102.

Plate wirings 103A and 103B are formed of metal plates, and have the function of electrically connecting electronic components mounted on surface wirings 104A, 104B to the mother board on which wiring board 101 is mounted, and also the function of transferring the heat from the electronic components to the mother board. The thickness of plate wirings 103A and 103B is not particularly limited, but is preferably 100 μm or more to ensure the mechanical strength of the wiring board.

The metal used for plate wirings 103A and 103B is not particularly limited, but is preferably copper, stainless steel, tungsten, molybdenum, aluminum, or an alloy thereof in order to have low thermal and electrical resistances. Using copper allows plate wirings 103A and 103B to have low thermal and electrical resistances because of its high thermal conductivity and low electrical resistance. Adding an additive such as Fe, Ni, P, Zn, Si, or Mg improves the properties such as softening temperature, strength, resin adhesion, and plating strength. Using stainless steel having a proper composition improves strength, workability, corrosion resistance, and other properties. Tungsten, molybdenum, and alloys thereof have low thermal expansion coefficients. Using them reduces the thermal expansion coefficient of a light emitting element, which is an electronic component to be mounted on wiring board 101, thereby improving the reliability of the light emitting element. Using aluminum results in reduction in weight and thermal resistance. Plate wirings 103A and 103B can be formed by subjecting one or more metal plates to etching, laser processing, or punching.

Wiring board 101 includes plate wirings 103A and 103B formed of a metal plate instead of vias 203 used in the conventional configuration including the ceramic substrate shown in FIGS. 13 to 15. As a result, wiring board 101 has a lower electrical resistance than the conventional configuration.

As described above, in the conventional configuration, vias 203 are used to electrically connect surface wirings 204 formed on the upper surface of the ceramic substrate and surface wirings 204 formed on the lower surface. The area for making an electrical connection between surface wirings 204 on the upper surface and surface wirings 204 on the lower surface is no larger than the total cross-sectional area of vias 203, thereby limiting the thermal and electrical resistances.

In contrast, plate wirings 103A and 103B formed of metal plates have a much larger total area than vias 203 as will now be described with reference to FIGS. 4A to 4D. As shown in FIG. 4A, the first surface of base 100 is provided with first top-surface wiring 104A and second top-surface wiring 104B. As shown in FIG. 4B, on the other hand, the second surface of base 100 is provided with first bottom-surface wiring 104C and second bottom-surface wiring 104D. As shown in FIG. 4C, first top-surface wiring 104A and first bottom-surface wiring 104C overlap with each other in first region 114A in the normal direction of the first surface. Similarly, second top-surface wiring 104B and second bottom-surface wiring 104D overlap with each other in second region 114B in the normal direction of the first surface. As understood from the comparison between FIGS. 3 and 4C, plate wirings 103A and 103B have substantially the same shapes as those of first region 114A and second region 114B, respectively, in the normal direction of the first surface. Surface wiring 104A and surface wiring 104C are connected to each other through plate wiring 103A and are at the same potential as each other. Similarly, surface wiring 104B and surface wiring 104D are connected to each other through plate wiring 103B and are at the same potential as each other.

In this configuration, the total areas for making an electrical connection between surface wirings 104A and 104C, and between surface wirings 104B and 104D are larger than the total cross-sectional areas of vias 203 formed in ceramic wiring board 201. Therefore, this configuration can make an electrical resistance lower. Furthermore, by making first region 114A to have substantially the same shape as that of plate wiring 103A, and by making second region 114B to have substantially the same shape as that of plate wiring 103B, plate wirings 103A and 103B can have a maximum area and a minimum electrical resistance.

Surface wirings 104A to 104D and plate wirings 103A and 103B are in different processed conditions because of their difference in thickness and other characteristics. Therefore, when the difference in dimension between first region 114A and plate wiring 103A is within ±50 μm, they are considered to be substantially identical to each other in shape and size. The same holds true for second region 114B and plate wiring 103B. The electrical and thermal resistances can be low when plate wirings 103A and 103B are larger in size than vias 203, even if not being identical in shape and size to first region 114A and second region 114B, respectively. By making plate wiring 103A smaller in area than surface wirings 104A and 104C, and by making plate wiring 103B smaller in area than surface wirings 104B and 104D, the influence of alignment between them can be reduced.

As shown in FIG. 4D, surface wiring 104B and surface wiring 104C overlap with each other in third region 115 in the normal direction of the first surface. In third region 115, however, the plate wiring is not provided. As a result, surface wiring 104B and surface wiring 104C are not connected to each other, thereby having different potentials from each other in terms of circuits. In other words, surface wirings 104B and 104C overlap with each other at some part through insulating portion 102 in the normal direction of the first surface, so that surface wirings 104B and 104C are isolated from each other. The provision of first, second, and third regions 114A, 114B, and 115 increases the degree of freedom in designing surface wirings 104A to 104D. As a result, surface wirings 104A to 104D can be designed to be easily mounted on light emitting element 111 or a mother board. Alternatively, surface wirings 104A and 104D may overlap with each other at some part through insulating portion 102 in the normal direction of the first surface, so that surface wirings 104A and 104D can be isolated from each other.

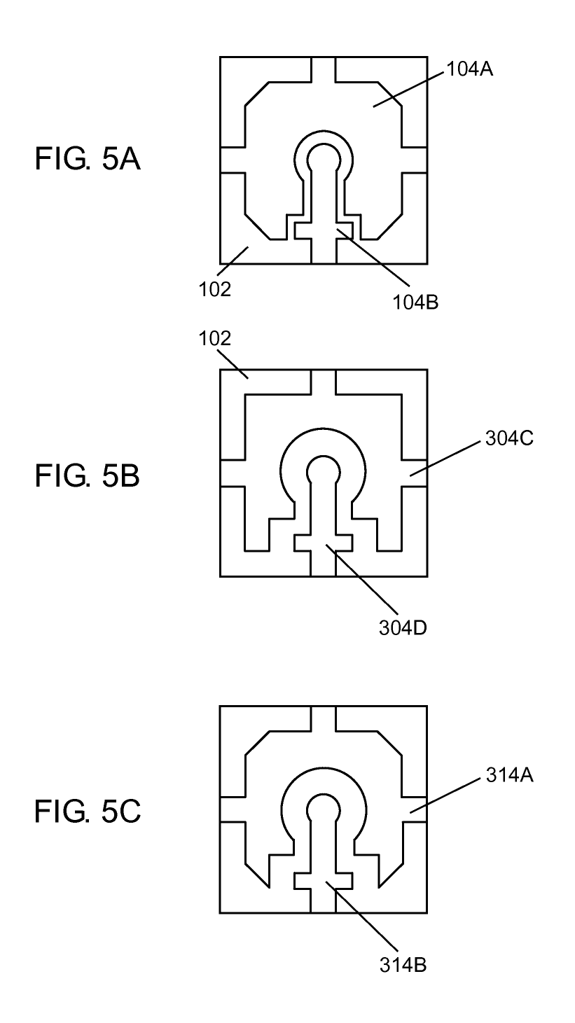

If third region 115 is absent, the surface wirings need to be formed as shown in FIGS. 5A and 5B. FIG. 5A is a plan view of a first surface of another wiring board according to the exemplary embodiment. FIG. 5B is a perspective plan view of a second surface of the wiring board shown in FIG. 5A. FIG. 5C is a plan view of regions in which top-surface wirings shown in FIG. 5A and bottom-surface wirings shown in FIG. 5B overlap with each other and are connected to each other through a plate wiring. Surface wirings 104A and 104B shown in FIG. 5A are identical in shape and size to surface wirings 104A and 104B, respectively, shown in FIG. 4A. When third region 115 is absent, however, as shown in FIG. 5B, surface wirings 304C and 304D are substantially identical in shape and size to surface wirings 104A and 104B. As shown in FIG. 5C, the total area of first region 314A where surface wirings 104A and 304C overlap with each other and second region 314B where surface wirings 104B and 304D overlap with each other is smaller than the total area of first and second regions 114A and 114B shown in FIG. 4C. Even so, the total area for making an electrical connection between surface wirings 104A and 304C, and between surface wirings 104B and 304D is larger than the area of vias 203 formed in ceramic wiring board 201. Therefore, this configuration has a lower electrical resistance than ceramic wiring board 201.

As described above, in ceramic wiring board 201 shown in FIGS. 13 to 15, vias 203 are formed by, for example, printing and filling, and then sintered integrally with ceramic insulating layer 202. This imposes limitations on the material of vias 203. In contrast, plate wirings 103A and 103B have no such limitations, allowing the use of high thermal-conductive metals, thereby achieving a low thermal resistance in addition to a low electrical resistance.

As will be understood from the example described below, wiring board 101 having a low electrical resistance can be produced by making the volume proportion of plate wirings 103A and 103B in base 100 not less than 20 vol %. When the volume proportion is not less than 40 vol %, not only the electrical resistance is reduced but also physical properties of wiring board 101, such as its thermal expansion coefficient can be controlled by the material of plate wirings 103A and 103B. In order to ensure the insulating properties of insulating portion 102 between plate wirings 103A and 103B, the volume proportion of plate wirings 103A and 103B in base 100 is preferably not more than 95 vol %.

In ceramic wiring board 201 shown in FIGS. 13 to 15, as ceramic insulating layer 202 is made thicker, the connection by vias 203 becomes more difficult, thereby increasing the electrical and thermal resistances. As described above, on the other hand, the use of plate wirings 103A and 103B increases the area for making an electrical connection between surface wirings 104A and 104C, and between surface wirings 104B and 104D. In other words, the use of plate wirings 103A and 103B can increase the area for making an electrical connection between surface wirings 104A, 104C and plate wiring 103A, and between surface wirings 104B, 104D and plate wiring 103B. The metal used is not limited, so that the electrical and thermal resistances can be made much lower than in the case of using a ceramic substrate. As plate wirings 103A and 103B is made thicker, the area for making an electrical connection between surface wirings 104A and 104C, and between surface wirings 104B and 104D can be larger than in the case of using a ceramic substrate, thereby further reducing the electrical and thermal resistances. For this reason, it is preferable that the thickness of plate wirings 103A and 103B be at least 100 μm.

It is also possible to expose a part of at least one of plate wirings 103A and 103B on a surface of base 100 other than the first and second surfaces. This allows the formation of solder fillets when base 100 is mounted on a mother board, thereby improving the mounting reliability.

The surface of plate wirings 103A and 103B may be plated with copper, tin, solder, or the like in order to facilitate the solder mounting.

The surfaces of plate wirings 103A and 103B (especially the surfaces to be bonded with insulating portion 102) may be subjected to a roughening treatment. The roughening treatment can be performed chemically or physically and improves the adhesion between plate wirings 103A, 103B and insulating portion 102.

Plate wirings 103A and 103B may have stepped structures. According to such structures, plate wirings 103A and 103B which are electrically isolated from each other through insulating portion 102 can be disposed under surface wirings 104A to 104D. This increases the volume of plate wirings 103A and 103B, thereby reducing the thermal resistance. The steps in plate wirings 103A and 103B can be formed by, for example, two etchings or etching from both sides.

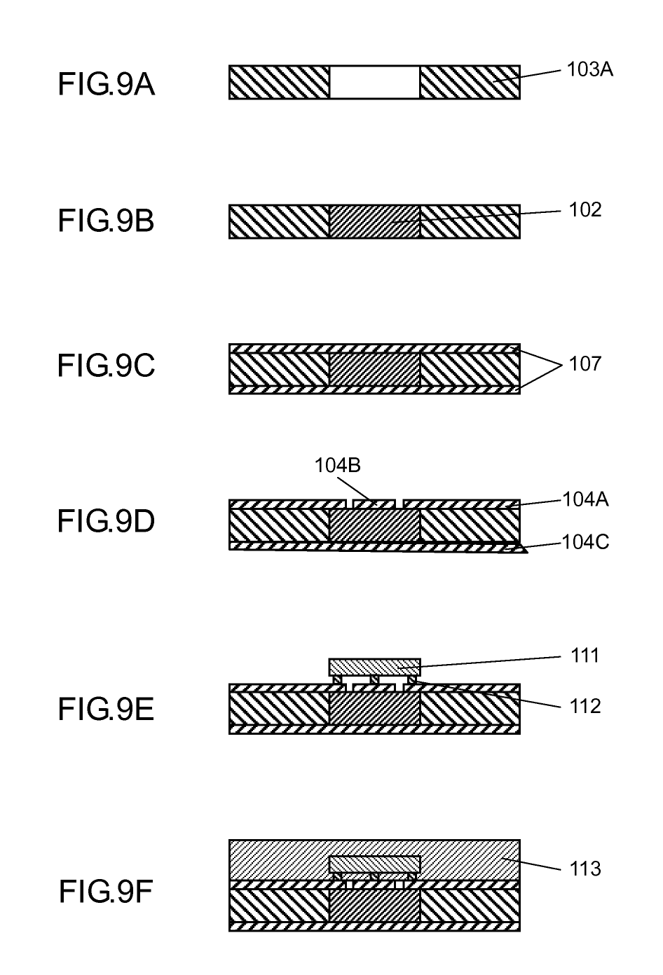

Surface wirings 104A to 104D are made of an electrically conductive material and are preferably subjected to metal plating. An electronic component mounted on surface wirings 104A and 104B, such as an LED or a semiconductor is electrically connected to plate wirings 103A and 103B through surface wirings 104A and 104B. Surface wirings 104A to 104D are formed both on plate wiring 103A or 103B and insulating portion 102 of base 100. One example of a method of forming surface wirings 104A to 104D will be described below with reference to FIGS. 9A to 9D. In FIG. 2, only surface wiring 104A is formed on both plate wiring 103A and insulating portion 102, but this illustration shows just one cross section.

As described above, in general, the size of the gap between wiring patterns largely depends on the thickness of the material of the wirings. FIG. 2 shows minimum wiring gap 109 between surface wirings 104A and 104B formed on the same surface, and minimum wiring gap 108 between plate wirings 103A and 103B formed on the same surface. Making surface wirings 104A and 104B thinner than plate wirings 103A and 103B increases the wiring accuracy of surface wirings 104A and 104B. This allows the formation of wiring patterns having a small wiring gap. As a result, minimum wiring gap 109 is made smaller than minimum wiring gap 108. In other words, the use of surface wirings 104A and 104B achieves wiring board 101 having a small wiring gap (narrower than the thickness of the metal plate), which cannot be achieved by the conventional wiring board including the metal plate. In particular, when the thickness of surface wirings 104A and 104B is made 50 pm or less, the wiring rule (line/space) can be made minute. As a result, a light emitting element can be mounted by flip-chip mounting with bumps, which is difficult in the conventional wiring board including the metal plate. If necessary, surface wirings 104C and 104D can be made thinner than plate wirings 103A and 103B, thereby making the minimum wiring gap between surface wirings 104C and 104D smaller than minimum wiring gap 108.

When formed by plating, surface wirings 104A and 104B (and surface wirings 104C and 104D) have a higher strength on plate wirings 103A and 103B than on insulating portion 102. More specifically, by making the area of surface wirings 104A and 104B formed on plate wirings 103A and 103B (the area on the first surface of base 100) 20% or more of the area of the first surface of base 100, surface wirings 104A to 104D have a high strength even at high temperatures of 200° C. to 350° C. The decrease in the strength of surface wirings 104A and 104B at high temperatures can also be suppressed by reducing the area of surface wirings 104A and 104B on insulating portion 102. It is preferable that the area be 40% or less. In the same manner, the area of surface wirings 104C and 104D (on the second surface of base 100) is preferably 20% or more of the area of the second surface of base 100, and more preferably 40% or less.

After being formed as wiring patterns, surface wirings 104A to 104D may be subjected to a surface treatment such as plating of gold, silver, tin, zinc, or nickel. Alternatively, surface wirings 104A to 104D may be formed by transferring wiring patterns formed on a release film onto insulating portion 102. Surface wirings 104C and 104D may be connected to a mother board by, for example, wire bonding.

As described above, wiring board 101 can be surface-mounted with a light emitting element having a wiring gap too small to be surface-mounted on the conventional wiring board including the metal plate. Furthermore, wiring board 101 is much lower in electrical resistance than the conventional wiring board including the ceramic substrate. In addition, the thermal resistance is low between the electronic components mounted on wiring board 101 and the mother board on which wiring board 101 is mounted.

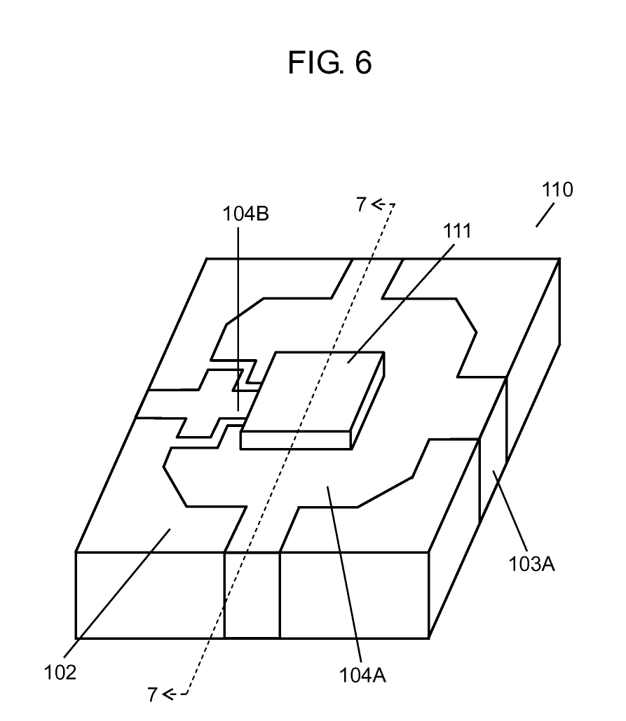

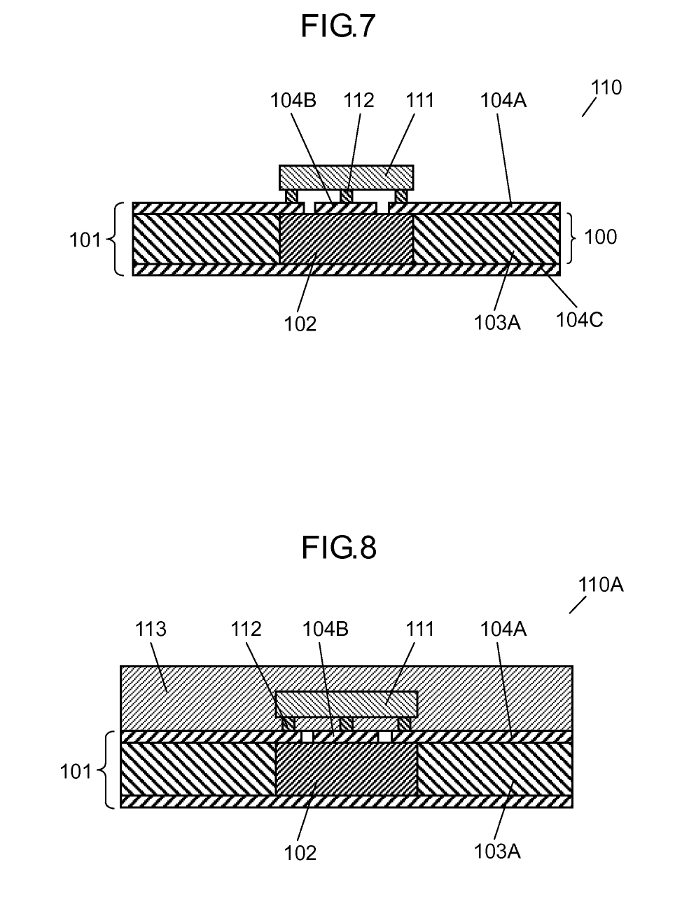

Light emitting device 110 including wiring board 101 and light emitting element 111 mounted thereon will now be described with reference to FIGS. 6 and 7. FIG. 6 is a perspective view of light emitting device 110. FIG. 7 is a sectional view taken along line 7-7 of light emitting device 110 shown in FIG. 6. In FIGS. 6 and 7, like components are labeled with same reference numerals as those in FIGS. 1 to 5C. Light emitting device 110 includes wiring board 101 and light emitting element 111 mounted on wiring board 101.

As shown in FIG. 7, light emitting element 111 is mounted on wiring board 101 via bumps 112. Wiring board 101 has the configuration described above with reference to FIGS. 1 to 5C.

Light emitting element 111 is composed of a semiconductor light emitting element such as an LED or an LD (semiconductor laser). These semiconductor light emitting elements can be used stably because of their high efficiency and longevity. LEDs are particularly preferable because of their inexpensiveness.

Light emitting element 111 can be produced by forming a semiconductor layer on a base material. Examples of the base material include sapphire, spinel, SiC, GaN, and GaAs. Examples of the semiconductor layer include BN, SiC, ZnSe, GaN, InGaN, and InGaAlN.

Light emitting element 111 is flip-chip mounted on wiring board 101 through conductive bumps 112 in such a manner that its light emitting surface is opposite to wiring board 101. Light emitting element 111 for flip-chip mounting includes a reflector electrode (made of aluminum, silver, gold, or an alloy thereof, for example). Light emitting element 111 emits light, which is reflected by the reflector electrode or wiring board 101 and transmitted outside. Flip-chip mounting has the advantage of preventing from generating the shadow of wire bonding and of having a large quantity of light without using a translucent electrode. Flip-chip mounting has the additional advantages of suppressing a temperature increase because the light emitting layer can be disposed near the wiring board, and of not causing wire breakage so as to have high reliability.

Light emitting device 110 may include a protection element (such as a Zener diode, a capacitor, or a varistor) to protect light emitting element 111 from overvoltage. A Zener diode decreases the resistance thereof when a voltage equal to the Zener voltage or greater is applied across it. Therefore, connecting a Zener diode in parallel with light emitting element 111 can prevent a voltage exceeding the Zener voltage from being applied to light emitting element 111 although an excessive voltage due to noise or other factors may be applied thereto. As a result, light emitting element 111 can be protected from excessive voltage, and hence from breakage or degradation in performance. The protection element may be disposed in insulating portion 102.

Light emitting element 111 and wiring board 101 are connected electrically and mechanically through conductive bumps 112. More specifically, bumps 112 are formed on surface wirings 104A and 104B, whereas light emitting element 111 is connected to surface wirings 104A and 104B through bumps 112.

Bumps 112 can be made of conductive adhesive containing a metallic filler instead of Au, alloys such as solder, or other materials. Bumps 112 may be formed on either light emitting element 111 or wiring board 101. After facing to each other with bumps 112 therebetween, light emitting element 111 and wiring board 101 may be electrically connected to each other by applying ultrasonic waves, heat, or load. Providing the plurality of bumps 112 facilitates the reduction of electrical and thermal resistances.

An underfill material may be filled between light emitting element 111 and wiring board 101 in order to improve heat conduction and mechanical strength. Examples of the underfill material include epoxy resins which are high in bond and mechanical strengths; and silicone resins and filler-containing resin compositions which are high in heat and weather resistances.

As described above, mounting light emitting element 111 on wiring board 101 including insulating portion 102, plate wirings 103A, 104B, and surface wirings 104A to 104D results in a low electrical resistance in the connection between light emitting element 111 and the mother board mounted with light emitting device 110. It also results in a low thermal resistance between light emitting element 111 and the mother board.

Light emitting element 111 can be mounted on wiring board 101 by, for example, the following methods: soldering, anisotropic conductive film (ACF) bonding, non-conductive film (NCF) bonding, and non-conductive paste (NCP) bonding. To flip-chip mount a semiconductor such as an LED, it is often the case to use gold-to-gold bonding, or gold-to-tin bonding. In the mounting with gold-to-gold bonding or gold-to-tin bonding, the gold bumps need to be deformed by thermocompression bonding or ultrasonic bonding. In addition, thermocompression bonding and reflow need to be performed at high temperatures of 300 to 350° C. Ultrasonic bonding also needs to increase the temperature as high as 200° C. As wiring board 101 has a higher elastic modulus, the gold bumps are easily deformed under low pressure, thereby reducing damage to the semiconductor and also increasing the bonding strength.

Wiring board 101 is superior to ordinary resin wiring boards in mounting light emitting element 111. More specifically, the elastic modulus of wiring board 101 can be controlled by the metallic material used for plate wirings 103A and 103B. Resin materials such as epoxy have a glass transition point. The elastic modulus varies greatly around the glass transition temperature, and significantly drops when exceeding the glass transition temperature. Wiring board 101 also contains resin as insulating portion 102. However, when the volume proportion of plate wirings 103A and 103B in base 100 is made not less than 20 vol %, the elastic modulus of wiring board 101 is hardly affected by the glass transition temperature of the resin used for insulating portion 102.

Unlike the conventional wiring board including the metal plate, wiring board 101 does not include an insulating layer on the metal plate, and insulating portion 102 is formed only between plate wirings 103A and 103B in such a manner as to be substantially as thick as plate wirings 103A and 103B. In this configuration, the elastic modulus of wiring board 101 at the mounting temperatures (200° C. to 350° C.) is dominated by the elastic modulus of the metallic material used for plate wirings 103A and 103B. The elastic modulus of wiring board 101 can be, namely, 2 GPs or more. As a result, the gold bumps can be easily deformed. The absolute value of the elastic modulus can be so high as ordinary resin materials cannot provide, possibly 10 GPs or more. This facilitates the deformation of the gold bumps under low pressure, thereby reducing damage to light emitting element 111.

At the time of mounting a light emitting element, the problem is warpage of a wiring board. If the wiring board is warped when a plurality of bumps are present, an uneven load is applied to the bumps, thereby decreasing reliability. However, the linear expansion coefficient of wiring board 101 is also dominated by the linear expansion coefficient of the metallic material used for plate wirings 103A and 103B similar to the case of the elastic modulus. In other words, the linear expansion coefficient of wiring board 101 is hardly affected by the glass transition temperature of the resin used for insulating portion 102. In addition, when surface wirings 104A to 104D and plate wirings 103A, 103B are made of either an identical material or materials having similar compositions, surface wirings 104A to 104D and base 100 have similar linear expansion coefficients. As a result, light emitting element 111 can be easily mounted even at high temperatures (200 to 350° C.) without causing wiring board 101 to be warped, thereby providing high mounting reliability.

In general, in the case of mounting light emitting element 111 at high temperatures, the adhesive strength between resin and a copper foil contained in a wiring board is low due to the high temperatures. Therefore, the strength of the electrode on which light emitting element 111 is mounted is a problem. In wiring board 101, the strength of surface wirings 104A to 104D formed on base 100 is affected by the adhesive strength between the resin and surface wirings 104A to 104D in the region where surface wirings 104A to 104D are bonded to insulating portion 102. In the region where surface wirings 104A to 104D are bonded to plate wirings 103A and 103B, on the other hand, if made by plating, surface wirings 104A to 104D are stable even at high temperatures, and have a high adhesive strength. The volume proportion of plate wirings 103A and 103B in base 100 is preferably not less than 20 vol %, and more preferably not less than 40 vol %. Since plate wirings 103A and 103B are as thick as insulating portion 102, the area proportion of plate wirings 103A and 103B in the first or second surface of base 100 should be not less than 20%, and more preferably not less than 40%. The processes at high temperatures degrade the resin. In the range of 200 to 350° C., the resin is susceptible to discoloration, especially on its surface in contact with air (oxygen). For this reason, it is preferable that insulating portion 102 be exposed as little as possible on the first surface and/or second surface of base 100.

Light emitting device 110A including cover layer 113 which covers light emitting element 111 will now be described with reference to FIG. 8. FIG. 8 is a sectional view of light emitting device 110A. In FIG. 8, like components are labeled with same reference numerals as those in FIGS. 1 to 7.

Cover layer 113 is bonded to the first surface of wiring board 101 and to light emitting element 111. Cover layer 113 protects light emitting element 111. The configuration of cover layer 113 can be controlled to perform the function of collecting or diffusing light.

It is preferable that cover layer 113 contain a phosphor (fluorescent agent) and a translucent material. The phosphor can convert the light (energy) of light emitting element 111 into light of a different wavelength. For example, the phosphor allows light emitting device 110A to emit light having a larger wavelength than that from light emitting element 111. Thus, cover layer 113 containing the phosphor enables the desired light to be taken out of light emitting device 110A. For example, light emitting device 110A can emit white light by a combination of blue light emitting element 111 and cover layer 113 including a yellow phosphor, or a combination of emitting element 111 capable of emitting ultraviolet to violet light and cover layer 113 including R, G, and B (and possibly yellow) phosphors. A phosphor may be made of a mixture of two or more materials. The use of a plurality of phosphors enables taking light of the desired color tone.

The wavelength of light can be effectively converted when the volume proportion of the phosphors in cover layer 113 is 3% or more. When the volume proportion is 80% or less, cover layer 113 can be easily formed.

Examples of the translucent material include light-transmitting resins such as silicone resins, epoxy resins, acrylic resins, urea resins, fluorine resins, and imide resins; glass; and silica gel. Silicone resins are preferable because of their weather resistance. Since it is preferable that the translucent material have high light-transmission properties, silicone resins are preferable from this standpoint. It is also preferable that the translucent material be either liquid at normal temperature or become liquid when heated. Mixing a liquid translucent material and a phosphor facilitates the dispersion of the phosphor, thereby improving the homogeneity of light.

Cover layer 113 may contain a filler for reducing thermal expansion or a filler for improving thermal conductivity, in addition to the phosphors. Cover layer 113 may further contain a solvent, a viscosity modifier, a light diffusing agent, a pigment, a discoloration-preventing agent, a flame retardant, and a wetting dispersant.

It is preferable in terms of strength that at least a part of the cavity between light emitting element 111 and wiring board 101 be filled with cover layer 113. The material to be filled into the cavity between light emitting element 111 and wiring board 101 may be different from the material used to cover light emitting element 111. Furthermore, cover layer 113 may have a multilayer structure.

A method for manufacturing wiring board 101 and light emitting device 110 will now be described with reference to FIGS. 9A to 9F. FIGS. 9A to 9F are sectional views showing steps of the method of manufacturing wiring board 101 and light emitting device 110. In FIGS. 9A to 9F, like components are labeled with same reference numerals as those in FIGS. 1 to 8, and the description thereof may be omitted.

First, as shown in FIG. 9A, a metal plate is patterned to form plate wirings 103A and 103B. In FIG. 9A, only plate wiring 103A is illustrated. The patterning can be performed by etching, laser processing, or punching.

Next, as shown in FIG. 9B, insulating portion 102 is formed between plate wirings 103A and 103B as follows. An uncured resin composition is filled between plate wirings 103A and 103B so as to be substantially as thick as plate wirings 103A and 103B, and then is cured so as to be integral with plate wirings 103A and 103B. The method of filling is not particularly limited; for example, screen printing can be used. Alternatively, insulating portion 102 may be formed by filling a molten thermoplastic resin. After being filled between plate wirings 103A and 103B, insulating portion 102 may be ground or cut to be substantially as thick as plate wirings 103A and 103B.

Next, as shown in FIG. 9C, surface wiring layers 107 thinner than plate wirings 103A and 103B are formed on the first and second surfaces of base 100, respectively. Surface wiring layers 107 may be formed by, for example, metal plating.

Next, as shown in FIG. 9D, surface wiring layers 107 are patterned to form surface wirings 104A to 104D. For example, a photoresist film is formed on surface wiring layers 107, then is exposed via a photomask, and is patterned by development. After this, surface wiring layers 107 are is etched excluding the wiring patterns, and the photoresist film is removed, thereby forming surface wirings 104A to 104D. The photoresist film can be made of a liquid resist or film. Since surface wirings 104A to 104D are formed by patterning, the wiring patterns can be formed to a level capable of mounting bare chips such as light emitting element 111 and be laid out in an arbitrary size and shape.

As shown in FIG. 3, surface wirings 104A and 104B are formed so that minimum wiring gap 109 between surface wirings 104A and 104B formed on the same surface can be smaller than minimum wiring gap 108 between plate wirings 103A and 103B.

Through these steps, wiring board 101 is completed. As described above, wiring board 101 includes base 100, and surface wirings 104A to 104D formed on the first and second surfaces of base 100. Base 100 includes plate wirings 103A and 103B formed of metal plates, and insulating portion 102 made of resin or a resin composition and integrally formed with plate wirings 103A and 103B. Surface wirings 104A and 104C are electrically connected to plate wiring 103A, whereas surface wirings 104B and 104D are electrically connected to plate wiring 103B.

As shown in FIG. 9E, light emitting device 110 is manufactured by mounting light emitting element 111 with bumps 112 on wiring board 101. Bumps 112 can be formed by wire, plating, ball mounting, or solder printing. Light emitting element 111 can be mounted on wiring board 101 by using ultrasonic or heat bonding, instead of soldering or conductive adhesive. It is alternatively possible to use a non-conductive adhesive layer.

It is also possible to provide a step of mounting an electrostatic discharge protection component such as a Zener diode or a varistor on wiring board 101 either before or after the step of mounting light emitting element 111.

Next, as shown in FIG. 9F, cover layer 113 is formed as follows. The material of cover layer 113 containing a phosphor and a translucent material is laid to cover light emitting element 111 and to be in contact with the first surface of wiring board 101. It is preferable that the material of cover layer 113 be either liquid or sheet-like because of the ease of its formation. When the material of cover layer 113 is liquid, it is possible to use screen printing, potting, or spraying. Alternatively cover layer 113 may be molded in a mold. At the time of disposing cover layer 113, it is preferable to reduce the ambient pressure so that cover layer 113 can be more easily filled into the cavity between light emitting element 111 and wiring board 101. It is also possible to fill a filling agent different from the material of cover layer 113 before the formation of cover layer 113. The use of the filling agent different from the material of cover layer 113 enables the use of a material with low viscosity and high filling property, or a highly insulating material. After being laid, the material of cover layer 113 is cured by heat so as to form cover layer 113.

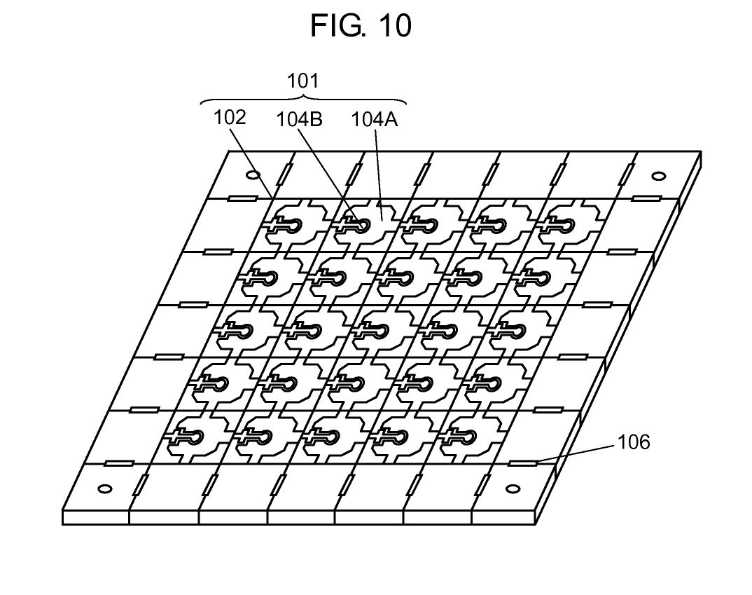

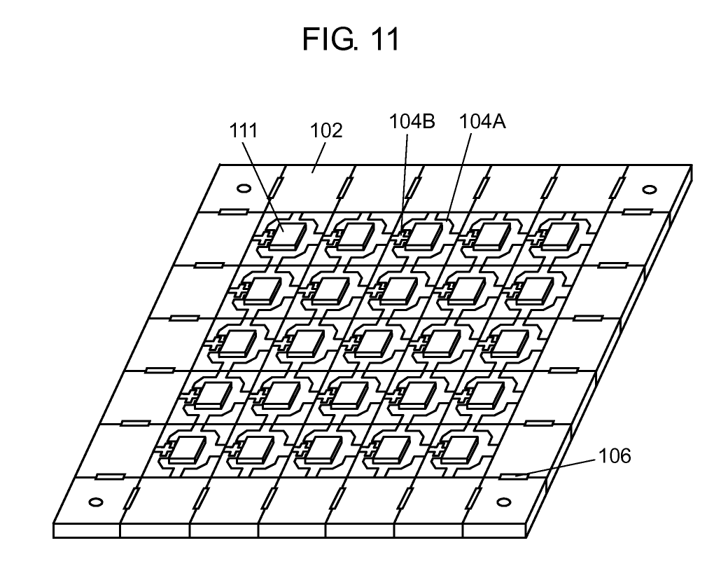

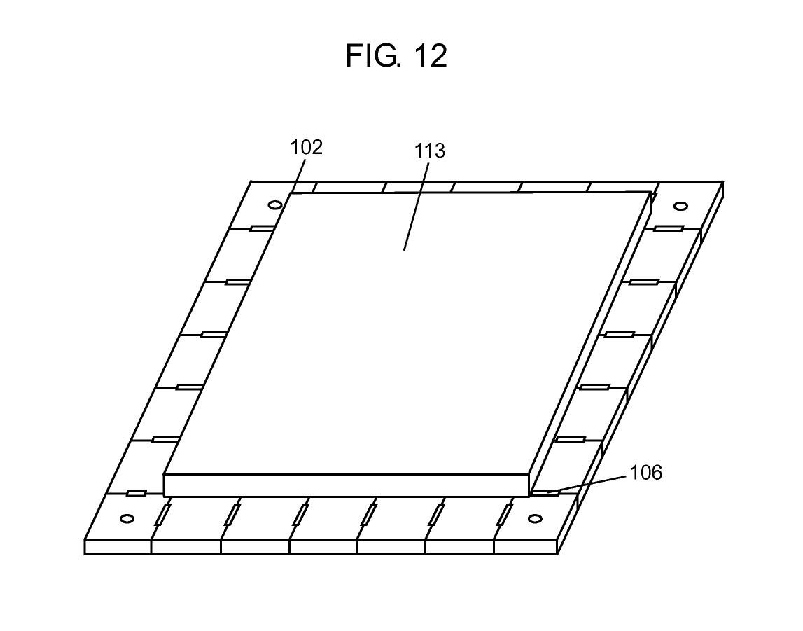

FIG. 10 is a perspective view of a plurality of wiring boards 101 arranged in an array. FIG. 11 is a perspective view of wiring boards 101 of FIG. 10 mounted with respective light emitting elements 111. FIG. 12 is a perspective view of wiring boards 101 which are mounted with light emitting elements 111, respectively, and are covered with cover layer 113 as shown in FIG. 9F.

As shown in FIG. 10, when a plurality of wiring boards 101 are arranged in the array as an assembly, light emitting elements 111 can be mounted with higher workability as compared with mounting individual light emitting elements 111 on the respective wiring boards 101 one by one. Furthermore, in wiring boards 101 arranged in the array, it is possible to handle plate wirings 103A and 103B as one unit. In addition, when wiring boards 101 arranged in the array are made into an assembly, it is possible to form a plurality of insulating portions 102, plate wirings 103A and 103B, and surface wirings 104A to 104D at one time, thereby increasing productivity.

As shown in FIGS. 10 to 12, markers 106 formed for dicing and/or mounting facilitate the process of dividing one unit consisting of a plurality of wiring boards 101 into the respective wiring boards 101 (individualization), or the process of mounting light emitting elements 111 onto the respective wiring boards 101. The individualization can be performed by, for example, dicing, laser processing, or mechanical cutting (for example, press-cutting). Furthermore, a plurality of modules can be formed by mounting electronic components such as an LED onto surface wirings 104A and 104B in wiring boards 101 arranged in the array, and then by cutting and separating wiring boards 101 from each other by dicing, laser processing, or mechanical cutting (for example, press-cutting).

### EXAMPLE

The following is a description of the analysis of the volume proportion of plate wirings 103A and 103B in base 100. More specifically, five wiring boards are manufactured corresponding to five different wiring boards 101 having different volume proportions of plate wirings 103A and 103B in base 100, namely, 10 vol %, 20 vol %, 40 vol %, 60 vol %, and 80 vol %. The measurement results include thermal resistance, elastic modulus, and bonding strength when light emitting element 111 is mounted on each of these wiring boards. Note that the present invention is not limited to the following example.

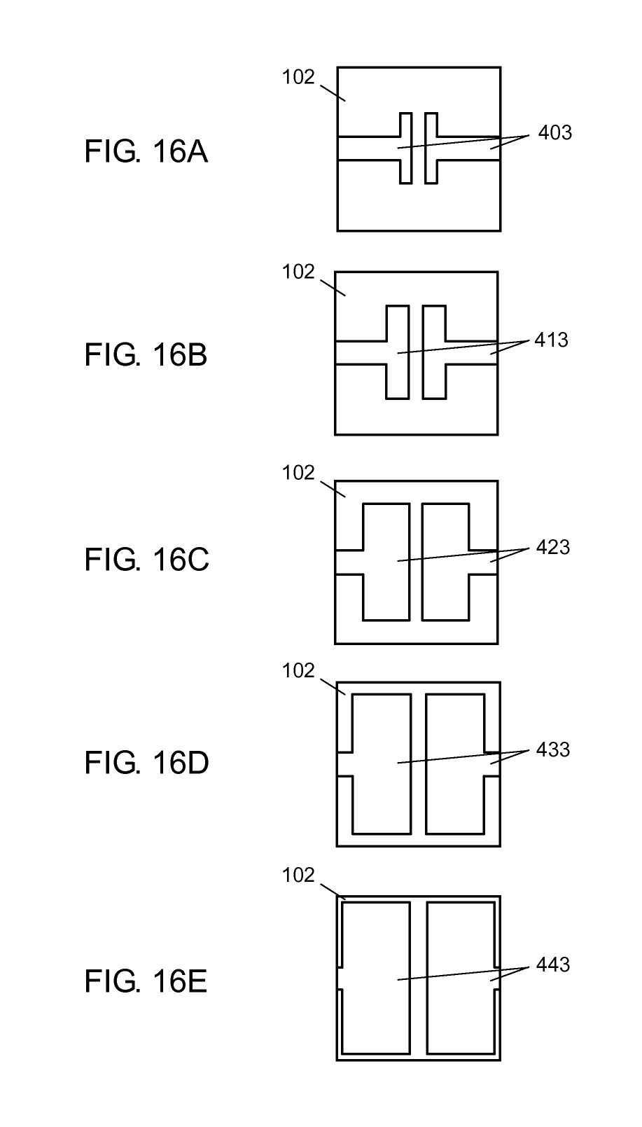

Regarding each of these five wiring boards, a square assembly of wiring boards of 50 mm is formed, and a 3.5 mm square wiring board is evaluated. Plate wirings 103A and 103B are made of a 0.3 mm thick copper alloy, and have a minimum wiring gap of 0.3 mm. FIGS. 16A to 16E show plan views of plate wirings 403 to 443, which are shown as schematic patterns of plate wirings 103A and 103B.

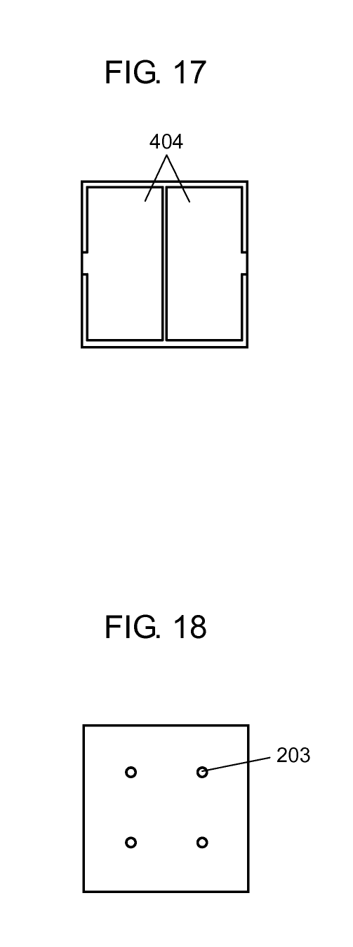

Similarly, different schematic patterns of surface wirings 104A to 104D are prepared which have different areas of the surface wirings on the first or second surface of base 100. The surface wirings are 25-μm-thick plated layers (electroless and electroplating), and the wiring patterns have a minimum wiring gap of 0.05 mm. The surface wirings are gold-plated. FIG. 17 shows surface wiring 404 as an example of the wiring pattern of the surface wiring to be combined with plate wiring 443. Insulating portion 102 is formed of a mixture of epoxy resin and a TiO₂ filler.

For comparison, an alumina wiring board and a resin wiring board are prepared. These wiring boards include, in place of plate wirings 103A and 103B, conductive vias 203 having a diameter of 200 μm formed in 3.5-mm-square substrates as shown in FIG. 18.

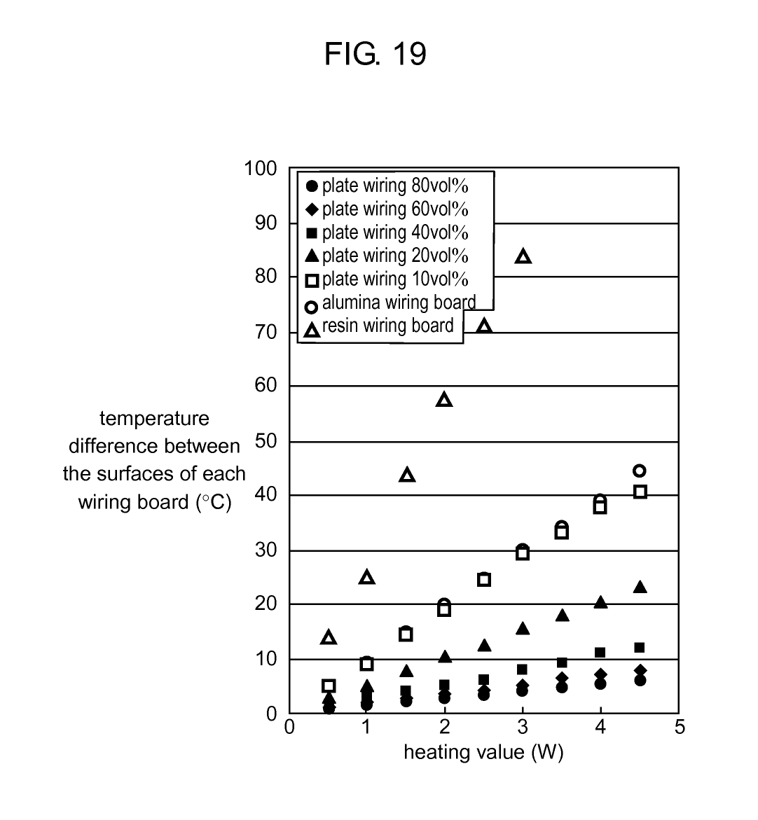

The thermal resistance is measured as follows. Light emitting element 111 as a heating element is mounted on surface wirings and heated by applying electric power thereto. At this moment, the difference in temperature is measured between the upper and lower surfaces of the wiring board (the first and second surfaces of base 100). FIG. 19 shows the temperature difference between each of the five wiring boards, the alumina wiring board, and the resin wiring board, depending on different heating values of light emitting element 111. The thermal resistances (the slopes in the graph of FIG. 19) calculated from FIG. 19 are shown in Table 1.

TABLE 1

| | | | | | | alumina | Resin |
|---|---|---|---|---|---|---|---|
| | | | | | | wiring | wiring |
| | wiring board | | | | | board | board |
| configuration | 16A | 16B | 16C | 16D | 16E | 18 | 18 |
| diagram | | | | | | | |
| volume | 10 | 20 | 40 | 60 | 80 | — | — |
| proportion | | | | | | | |
| vol % | | | | | | | |
| thermal | 9.8 | 5.1 | 2.6 | 1.7 | 1.3 | 9.8 | 28.9 |
| resistance | | | | | | | |
| ° C./W | | | | | | | |

In the wiring board shown in FIG. 16A in which the volume proportion of plate wiring 403 in the base is 10 vol %, the thermal resistance is similar to that of the alumina wiring board. In contrast, in the wiring board shown in FIG. 16B in which the volume proportion of plate wiring 413 in the base is 20 vol % or more, the thermal resistance is lower than that of the alumina wiring board. The higher the volume proportion of the plate wiring in base 100 is, the lower the thermal resistance of wiring board 101 is, and hence, the lower the temperature of light emitting element 111 is.

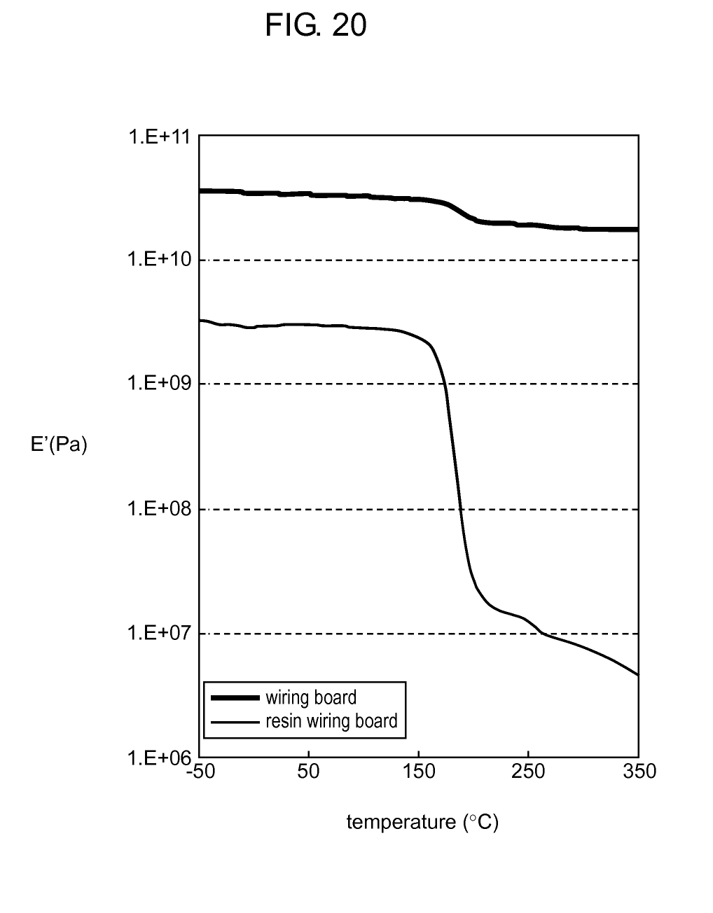

FIG. 20 shows the measurement results of the elastic modulus in the thickness direction (the direction orthogonal to the first and second surfaces of base 100) of the wiring board shown in FIG. 16B. For comparison, the results of the resin wiring board are also shown. In the resin wiring board, the elastic modulus suddenly drops at around 176° C. which is the glass transition temperature. The elastic modulus of wiring board 101 also slightly decreases at around the glass transition temperature because insulating portion 102 is made of resin. The volume proportion of plate wiring 413 in the base is 20 vol %, and plate wiring 413 is made of a metal having a higher stiffness than the resin. For this reason, the elastic modulus of the wiring board shown in FIG. 16B has different features from the resin wiring board. More specifically, the elastic modulus of the wiring board is 10 GPs or more, which is at least twice that of the resin wiring board. The high elastic modulus of the wiring board is kept above the glass transition temperature. Since plate wiring 413 and insulating portion 102 are substantially the same in thickness, the elastic modulus of the wiring board in the thickness direction is close to the value obtained by multiplying the elastic modulus of the materials used for plate wiring 413 and insulating portion 102 by the volume proportion (the volume proportion in base 100). This achieves a high elastic modulus.

Next, the wiring board shown in FIG. 16C and the resin wiring board for comparison are subjected to a pull test to evaluate the dependence of the bonding strength between the wiring board and the gold balls and between the resin wiring board and the gold balls on the thermocompression bonding load when light emitting element 111 is mounted by gold-to-gold bonding. In the wiring board shown in FIG. 16C, the volume proportion of plate wiring 423 in the base is 40 vol %.

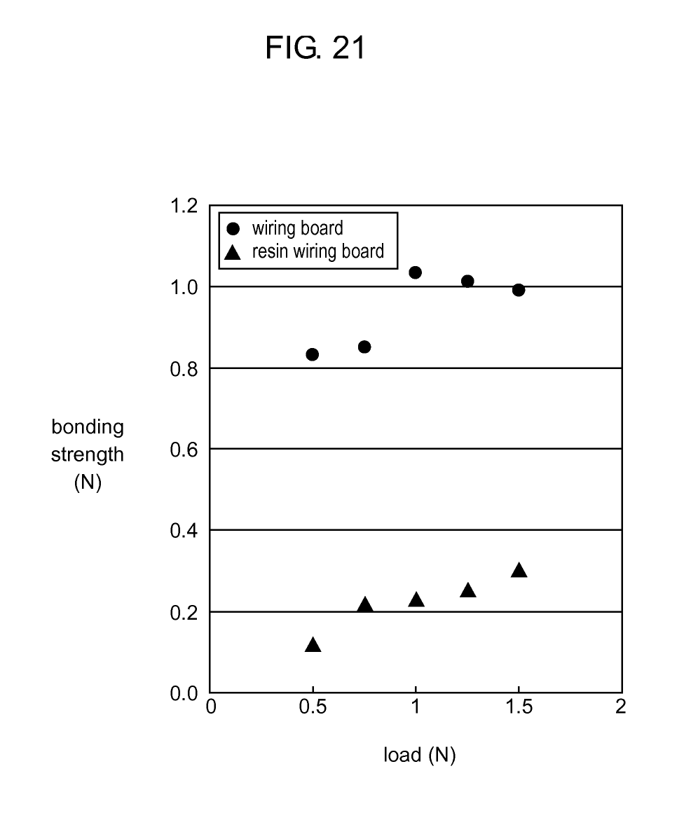

Light emitting element 111 to which the gold balls are bonded by ultrasonic bonding is thermocompression-bonded to the wiring with a flip-chip bonder at a heating temperature of 350° C. The results are shown in FIG. 21. According to the evaluation results shown in FIG. 21, the resin wiring board shows a low bonding strength, especially when the load is low. The reason for this is that the heating temperature higher than the glass transition temperature causes the elastic modulus of the resin wiring board to be low, failing to apply a sufficient load to the gold balls. The elastic modulus of the wiring board, on the other hand, is high even at high temperatures, indicating good bonding strength even with a low load.

Next, light emitting element 111 is die-bonded by high-temperature soldering in order to evaluate the shear strength of the surface wirings at 300° C. Samples of different wiring boards are prepared in which the area of the surface wirings formed on the first surface of the base is changed in cases that the volume proportions of the plate wirings in the base are 20 vol % (FIG. 16B), 40 vol % (FIG. 16C), 60 vol % (FIG. 16D), and 80 vol % (FIG. 16E), respectively. Table 2 shows the evaluation results of the shear strength. Samples whose surface wirings are damaged by 1 kg of load are shown as “NG”, whereas those whose surface wirings are not damaged are shown as “OK”. The samples unable to be formed are shown as “−”.

As apparent from Table 2, high bonding strength can be obtained by setting the area of the surface wirings formed on the plate wiring at 20% or more of the area of the first or second surface of the base. High bonding strength can alternatively be obtained by setting the area of the surface wirings formed on the insulating portion at 40% or less of the area of the first or second surface of the base.

TABLE 2

| | | | | area of the surface wirings on the insulating portion/ | | | | | | | | |
|---|---|---|---|---|---|---|---|---|---|---|---|---|
| | | | | area of the wiring board (%) | | | | | | | | |
| | | | | 10 | 20 | 30 | 40 | 50 | 60 | 70 | 80 | 90 |
| volume of the | 20 | area of the surface | 10 | OK | OK | OK | OK | NG | NG | NG | NG | NG |
| plate wirings/volume | | wirings on the | 20 | OK | OK | OK | OK | OK | OK | OK | OK | — |
| of the wiring | 40 | plate wirings/area | 10 | OK | OK | OK | OK | NG | NG | — | — | — |
| board (vol %) | | of the wiring | 20 | OK | OK | OK | OK | OK | OK | — | — | — |
| | | board (%) | 30 | OK | OK | OK | OK | OK | OK | — | — | — |
| | | | 40 | OK | OK | OK | OK | OK | OK | — | — | — |
| | 60 | | 10 | OK | OK | OK | OK | — | — | — | — | — |
| | | | 20 | OK | OK | OK | OK | — | — | — | — | — |
| | | | 30 | OK | OK | OK | OK | — | — | — | — | — |
| | | | 40 | OK | OK | OK | OK | — | — | — | — | — |
| | | | 50 | OK | OK | OK | OK | — | — | — | — | — |
| | | | 60 | OK | OK | OK | OK | — | — | — | — | — |
| | 80 | | 10 | OK | OK | — | — | — | — | — | — | — |
| | | | 20 | OK | OK | — | — | — | — | — | — | — |
| | | | 30 | OK | OK | — | — | — | — | — | — | — |
| | | | 40 | OK | OK | — | — | — | — | — | — | — |
| | | | 50 | OK | OK | — | — | — | — | — | — | — |
| | | | 60 | OK | OK | — | — | — | — | — | — | — |
| | | | 70 | OK | OK | — | — | — | — | — | — | — |
| | | | 80 | OK | OK | — | — | — | — | — | — | — |

The present disclosure provides a wiring board having low thermal and electrical resistances and including wirings fine enough to be used for bare chip mounting. Mounting a light emitting element onto the wiring board achieves a light emitting device which can suppress a temperature rise in the light emitting element.

What is claimed is:

1. A wiring board comprising:
a base having a first surface and a second surface opposite to the first surface, the base including:
a plurality of plate wirings including first and second plate wirings and formed of metal plates; and
an insulating portion made of resin, a resin composition, or a glass composition and integrally formed with the plurality of plate wirings so as to be substantially as thick as the plurality of plate wirings,
a plurality of top-surface wirings metal-plated on the first surface so as to be thinner than the plurality of plate wirings, and including first and second top-surface wirings electrically connected to the first and second plate wirings, respectively; and
a plurality of bottom-surface wirings metal-plated on the second surface so as to be thinner than the plurality of plate wirings, and including first and second bottom-surface wirings electrically connected to the first and second plate wirings, respectively,
wherein a minimum wiring gap between the plurality of top-surface wirings is smaller than a minimum wiring gap between the plurality of plate wirings,
the first plate wiring has substantially the same shape as that of a region in which the first top-surface wiring and the first bottom-surface wiring overlap with each other in a normal direction of the first surface, and
the first top-surface wiring and the first bottom-surface wiring are connected to each other through the first plate wiring.

2. The wiring board according to claim 1, wherein
the second plate wiring has substantially the same shape as that of a region in which the second top-surface wiring and the second bottom-surface wiring overlap with each other in the normal direction of the first surface; and
the second top-surface wiring and the second bottom-surface wiring are connected to each other through the second plate wiring.

3. The wiring board according to claim 2, wherein the second top-surface wiring and the first bottom-surface wiring overlap with each other at some part through the insulating portion in the normal direction of the first surface, so that the second top-surface wiring and the first bottom-surface wiring are isolated from each other.

4. The wiring board according to claim 1, wherein the first top-surface wiring and the second bottom-surface wiring overlap with each other at some part through the insulating portion in the normal direction of the first surface, so that the first top-surface wiring and the second bottom-surface wiring are isolated from each other.

5. The wiring board according to claim 1, wherein the plurality of plate wirings are at least partially surface-treated.

6. The wiring board according to claim 1, wherein the plurality of plate wirings are made of at least one of copper, aluminum, tungsten, molybdenum, and alloys thereof.

7. The wiring board according to claim 1, wherein at least one of the plurality of plate wirings is partially exposed on a surface of the base other than the first surface and the second surface.

8. The wiring board according to claim 1, wherein a total volume proportion of the plurality of plate wirings in the base is in a range from 20 vol % to 95 vol %, inclusive.

9. The wiring board according to claim 8, wherein
the plurality of top-surface wirings is formed on the insulating portion in a total area of at least 40% of an area of the first surface of the base; and
the plurality of bottom-surface wirings is formed on the insulating portion in a total area of at least 40% of an area of the second surface of the base.

10. The wiring board according to claim 1, wherein a volume proportion of the plurality of plate wirings in the base is in a range from 40 vol % to 95 vol %, inclusive.

11. The wiring board according to claim 10, wherein
the plurality of top-surface wirings is formed on the plurality of plate wirings in a total area of at least 20% of an area of the first surface of the base; and
the plurality of bottom-surface wirings is formed on the plurality of plate wirings in a total area of at least 20% of an area of the second surface of the base.

12. The wiring board according to claim 10, wherein
the plurality of top-surface wirings is formed on the insulating portion in a total area of at most 40% of an area of the first surface of the base; and
the plurality of bottom-surface wirings is formed on the insulating portion in a total area of at most 40% of an area of the second surface of the base.

13. The wiring board according to claim 1, wherein the insulating portion is a mixture of resin and a filler and the filler includes at least one of Al₂O₃, MgO, SiO₂, BN, AlN, Si₃N₄, polytetrafluoroethylene, MgCO₃, Al(OH)₃, Mg(OH)₂, AlO(OH), and TiO₂.

14. A method for manufacturing a wiring board, comprising:
forming a plurality of plate wirings including first and second plate wirings by patterning a metal plate;
forming a base including the plurality of plate wirings and an insulating portion by filling resin, a resin composition, or a glass composition between the plurality of plate wirings such that the insulating portion can be integrated with the plurality of plate wirings and be as thick as the plurality of plate wirings;
forming a pair of surface wiring layers by metal plating on a first surface and a second surface opposite to the first surface of the base such that the surface wiring layers are thinner than the plurality of plate wirings and electrically connected to the plurality of plate wirings; and
forming a plurality of top-surface wirings including first and second top-surface wirings by patterning one of the surface wiring layers formed on the first surface of the base, and also forming a plurality of bottom-surface wirings including first and second bottom-surface wirings by patterning the other of the surface wiring layers formed on the second surface of the base,
wherein when forming the plurality of top-surface wirings and the plurality of bottom-surface wirings, the surface wiring layers are patterned so as to satisfy following conditions:
a minimum wiring gap between the top-surface wirings and a minimum wiring gap between the bottom-surface wirings are smaller than a minimum wiring gap between the plate wirings;
a region in which the first top-surface wiring and the first bottom-surface wiring overlap with each other in a normal direction of the first surface has substantially the same shape as that of the first plate wiring; and
the first top-surface wiring and the first bottom-surface wiring are connected to each other through the first plate wiring.

15. An assembly comprising a plurality of the wiring boards as defined in claim 1 arranged in an array.

16. A light emitting device comprising:
the wiring board as defined in claim 1; and
a light emitting element mounted on the first surface of the base of the wiring board and electrically connected to the plurality of top-surface wirings.

17. A method for manufacturing a light emitting device, comprising:
forming a plurality of plate wirings including first and second plate wirings by patterning a metal plate;
forming a base including the plurality of plate wirings and an insulating portion by filling resin, a resin composition, or a glass composition between the plurality of plate wirings such that the insulating portion can be integrated with the plurality of plate wirings and be as thick as the plurality of plate wirings;
forming a pair of surface wiring layers by metal plating on a first surface and a second surface opposite to the first surface of the base such that the surface wiring layers are thinner than the plurality of plate wirings and electrically connected to the plurality of plate wirings;
forming a plurality of top-surface wirings including first and second top-surface wirings by patterning one of the surface wiring layers formed on the first surface of the base, and also forming a plurality of bottom-surface wirings including first and second bottom-surface wirings by patterning the other of the surface wiring layers formed on the second surface of the base; and
mounting a light emitting element onto the first surface of the base and electrically connecting the light emitting element to the plurality of top-surface wirings,
wherein when forming the plurality of top-surface wirings and the plurality of bottom-surface wirings, the surface wiring layers are patterned so as to satisfy following conditions:
a minimum wiring gap between the top-surface wirings and a minimum wiring gap between the bottom-surface wirings are smaller than a minimum wiring gap between the plate wirings;
a region in which the first top-surface wiring and the first bottom-surface wiring overlap with each other in a normal direction of the first surface has substantially the same shape as that of the first plate wiring; and
the first top-surface wiring and the first bottom-surface wiring are connected to each other through the first plate wiring.

18. The method for manufacturing the light emitting device according to claim 17, wherein
the wiring board is one of a plurality of wiring boards; and
the plurality of wiring boards are arranged in an array to form an assembly,
wherein the method further comprising individualizing the assembly integrated with the cover layer by dicing.
